(19) United States
(12) Patent Application Publication
(10) Pub. No.: US 2016/0141318 A1
(43) Pub. Date: May 19, 2016

(54) METHOD AND SYSTEM FOR ASSEMBLY OF RADIOLOGICAL IMAGING SENSOR

(71) Applicant: TELEDYNE DALSA, INC., Waterloo (CA)

(72) Inventor: Anton Van ARENDONK, Waterloo (CA)

(21) Appl. No.: 14/898,427

(22) PCT Filed: Jun. 28, 2013
(86) PCT No.: PCT/CA2013/000611

§ 371 Date: Dec. 14, 2015

(51) Int. Cl. H01L 27/146

(52) U.S. Cl. CPC H01L 27/1463; H01L 27/14663; H01L 27/14625

(57) ABSTRACT

An imaging sensor having a coupling portion consisting of a plurality of resist portions that act as a light guide to direct light from a fiber optic plate to an imaging die layer. The resist portions can be formed through a photolithographic process to define an air gap between adjacent resist portions. The imaging sensor can further include a scintillator layer that can convert ionizing radiation, such as X-rays and gamma rays used in medical imaging, into optical radiation for detection by the imaging die layer.

### FIELD OF THE INVENTION

The present invention relates generally to processes and materials for assembly of radiological imaging sensors, such as for medical applications including medical imaging and multi-spectral imaging.

### BACKGROUND OF THE INVENTION

A medical imaging sensor typically comprises a semiconductor chip having an array of photosensitive pixels, each pixel includes a photo detector and an active amplifier. In addition, a scintillator can covers the semiconductor chip and a fiber optic plate is positioned between the scintillator and the semiconductor chip. The scintillator layer converts incoming ionizing radiation (e.g. X-rays or gamma rays) into visible light. The above-described elements of the medical imaging sensor may be contained in a package from which a connection cable may extend to a computer system for processing acquired images.

FIG. 1 is a cross sectional view of a prior art radiological imaging sensor 100 having a substrate 101 and based on a thermal-cured adhesive process. Imaging die 104 having an active sensor area 105 is stacked on top of substrate 101, and is secured in place thereon by a thermally cured adhesive layer 103. Similarly, fiber optic plate 106 is stacked on imaging die 104, and is secured in place using thermally cured adhesive layer 110.

It is noted that the thermal cure process is very batch oriented, and also very time-consuming, in the order of 12 to 18 hours to limit the stress per cycle typically. It is evident that typically 2 thermal cure cycles may be required in assembling imaging sensor 100. Additionally, using adhesive layers 110 to bond the imaging die 104 to the fiber optic plate 106 can be disadvantageous as once the adhesives cure, the separate components cannot be reworked (disconnected and reassembled) when needed. Additionally, each of the semiconductor chip and fiber optic plate can be expensive and the inability to rework these components is problematic.

In addition, those skilled in the art would appreciate that the use of adhesives between the semiconductor chip (e.g. imaging die layer 104 containing the photosensitive pixels in the active sensor area 105) and the fiber optic plate 106 causes optical cross-talk between the pixels. That is, the light information, or at least a portion of the light photons generated by the scintillator layer 107 guided through the fiber optic plate 106 (shown as light rays 111) and intended for a particular pixel in the sensor area 105, is also caused by the adhesive layer 110 to enter into adjacent neighboring pixels that were not intended for receiving the light information (see scattering or cross talk effect 112). As discussed earlier, the light information is generated by exposing the imaging sensor 100 (and specifically scintillator 107) to x-ray radiation. In this manner, the adhesive layer 110 and the use of thermally cured adhesives is disadvantageous as it interferes with and scatters the path of the light rays or photons such as to cause optical cross-talk and inaccurate sensor readings on the active sensor area 105.

For example, a bond line of the optical adhesive layer 110 can cause light rays to bounce in between the pixels and the fiber optic plate 106, causing in inter-pixel cross talk effect (which is correlated to decreasing the modulation transfer function). This cross talk (and thus decrease to MTF) increases further when the bond line of optical adhesive layer 110 is increased in thickness and can cause a circular projection resulting in the light rays to hit the pixel and its neighboring pixels in, for example, a circular pattern.

Although an adhesive layer 110 has been described in relation to FIG. 1, other types of permanent or semi-permanent bonding techniques between the fiber optic plate 106 and the imaging die layer 104 and/or sensor area 105 which can not be easily reworked would be similarly disadvantageous.

Scintillator layer 107 may be either a deposited layer, or else may be applied as a strip (polyimide and or other), secured appropriately in place using a press-on cover.

Those skilled in the art will appreciate that a wire bond connection 109 is provided between the imaging die layer 104 and the substrate layer 101.

### SUMMARY OF THE INVENTION

Provided is a method of assembling an imaging sensor. The imaging sensor includes a non-adhesive coupling layer between the fiber optic plate and the semiconductor chip or specifically the imaging die layer such as to minimize optical cross talk of photons intended for particular pixels within the imaging die layer. In one aspect, the resist portions are made of organic material such as SU-8, BCB or any other photo sensitive layer that can be patterned and allows for a high height-to-width aspect ratio (e.g. above 1.5).

The imaging sensor comprises a substrate plate having an upper surface; an imaging die layer on the upper surface of the substrate plate, the imaging die layer having an active image sensor region, the active image sensor region comprising a plurality of pixels, the pixels adapted for receiving light photons, each said pixel having a pixel area for receiving light photons; a fiber optic plate provided above the imaging die layer having a plurality of parallel wave guides and at least one of the pixels corresponding to at least two wave guides; and a coupling portion comprising a plurality of resist portions, each of the resist portions being located adjacent to a corresponding one of the pixels and having a resist portion area corresponding to at least a portion of the pixel area of the corresponding one of the pixels, each resist portion configured to act as a light guide such as to receive and direct the light photons from the fiber optic plate to the corresponding one of the pixels directly adjacent thereto, the coupling portion located between the imaging die layer and the fiber optic plate, adjacent resist portions defining an air gap.

### BRIEF DESCRIPTION OF THE DRAWINGS

The invention will now be described by way of example only with reference to the following drawings in which:

FIG. 1 is a cross sectional view of a prior art medical imaging sensor having a substrate and based on a thermal-cured adhesive process;

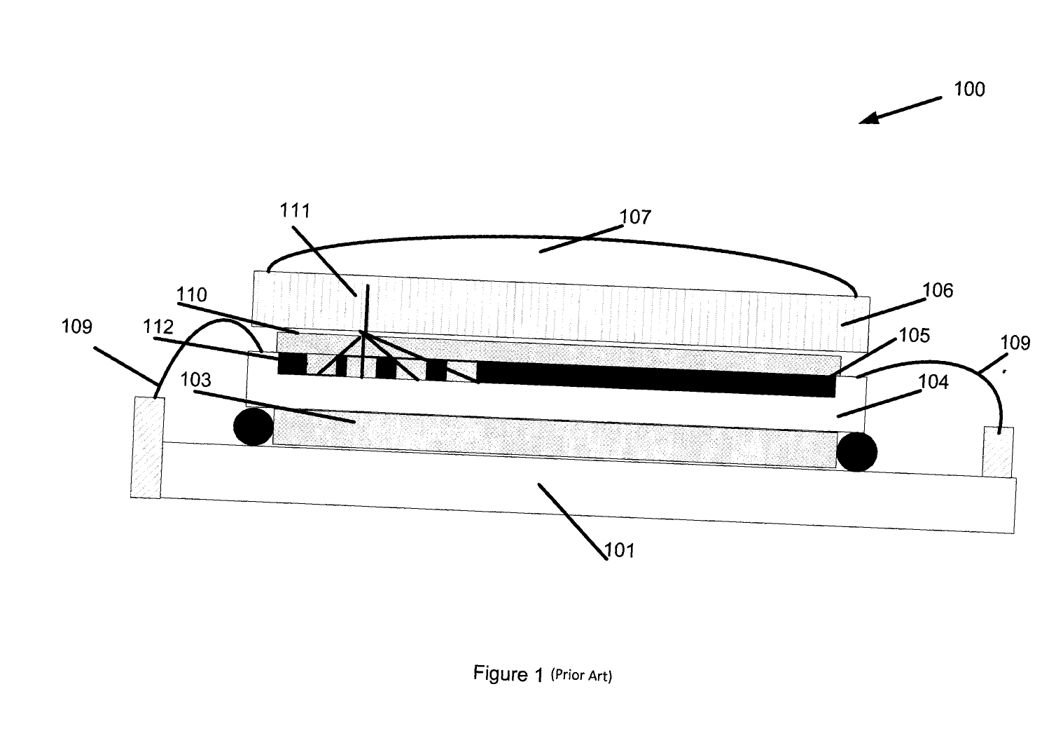

FIG. 2 shows one embodiment of a non-adhesive coupling between a fiber optic plate and a semiconductor device (e.g. particularly the imaging die layer of the semiconductor device);

FIG. 3 shows exemplary refractive index of the coupling portion material;

FIG. 4 shows an example implementation of an imaging sensor of FIG. 2 using a removable mechanical clamp for securing the layers; and

FIG. 5 shows an exploded view of the clamp of FIG. 4.

### DETAILED DESCRIPTION

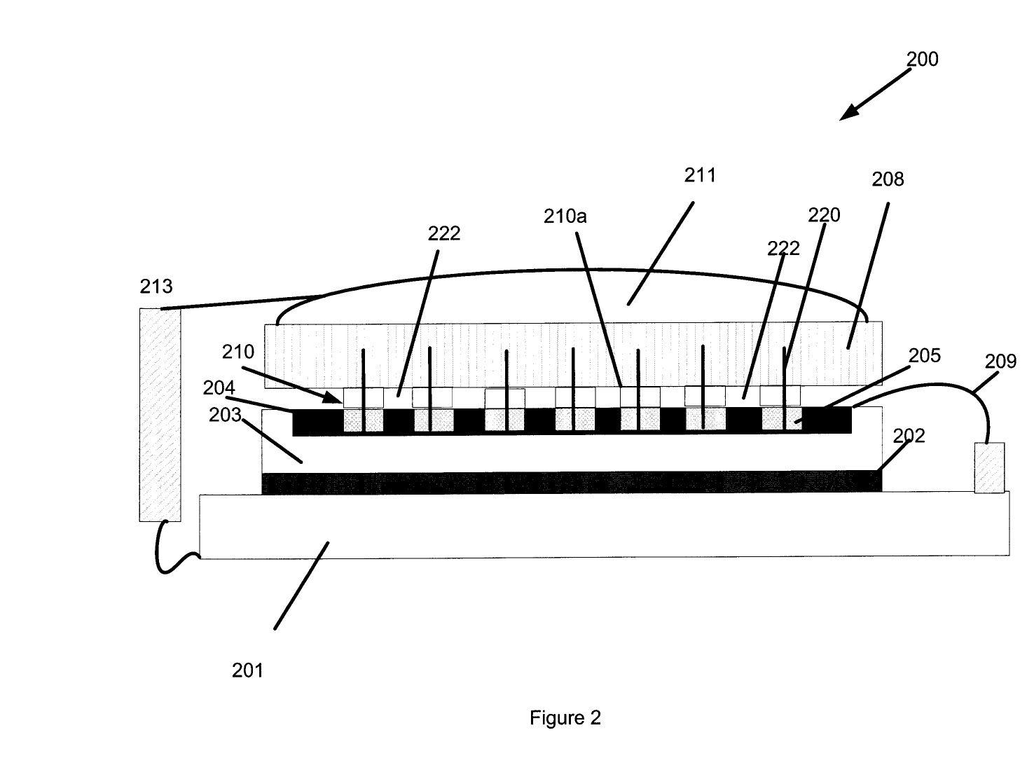

FIG. 2 illustrates one embodiment of an imaging sensor device 200 (e.g. a medical imaging sensor) comprising a substrate plate 201. The substrate plate 201 can include for example a transparent glass plate, CE-7, metal, a thermally cured U.V. adhesive or any other material envisaged by a person skilled in the art selected as a substrate. The substrate plate 201 is adapted to protect the sensor device 200 from external factors, including environmental conditions, such as moisture and temperature, for example.

The imaging sensor 200 further comprises an imaging die layer 203 disposed an upper surface of the substrate plate 201. The imaging die layer 203 can include a silicon substrate layer and can have an active sensor region 204. The active image sensor region 204 comprises a plurality of pixels that are adapted for receiving light photons. The pixels have a pixel are for receiving light photons on the upper surface of the active sensor region 204. The pixel may be comprised of either charge coupled device (CCD), single-photon avalanche diode (SPAD), complementary metal oxide semiconductor (CMOS) sensor elements, amorphous silicon detectors, and organic material-based light sensors.

In some embodiments, the imaging die layer 203 can be made of a mono-crystalline silicon or any other suitable material, including, for example, flat panel detectors made on glass substrates and plastic electronics.

The term upper surface is used with respect to imaging die layer 203 to refer to exposing the image sensor region 204 to detect radiation from fiber optic plate 208 for either a top oriented sensor or a back-side illuminated sensor. In one embodiment illustrated, the imaging die 203 is secured in place by a first layer of adhesive 202 (e.g an ultra-violet curable adhesive) applied to the upper side of the substrate plate 201 for securement therewith. Adhesive 202 can be a U.V. cured adhesive or a thermally cured adhesive. Adhesive 202 can be transparent or non-transparent.

Referring to FIG. 2, the fiber optic plate 208 is placed on the top surface of imaging die 203. The fiber optic plate 208 can be clear or transparent. The fiber optic plate 208 serves to guide the light rays generated by the scintillator layer 211 to a set of pre-defined pixels. Fiber optic plate 208 comprises a plurality of parallel optical wave guides that direct light energy from the scintillator layer 211 to the top surface of the imaging die 203. Each pixel can have a corresponding one or more wave guides of fiber optic plate 208 that direct photons to the pixel. Each of the parallel wave guides can have a core of approximately 8 microns, or 25 microns, for example, and are separated by a surrounding cladding. A pixel of say 100 microns could have multiple fibers (i.e. wave guides) of fiber optic plate 208 exposing light into a single pixel.

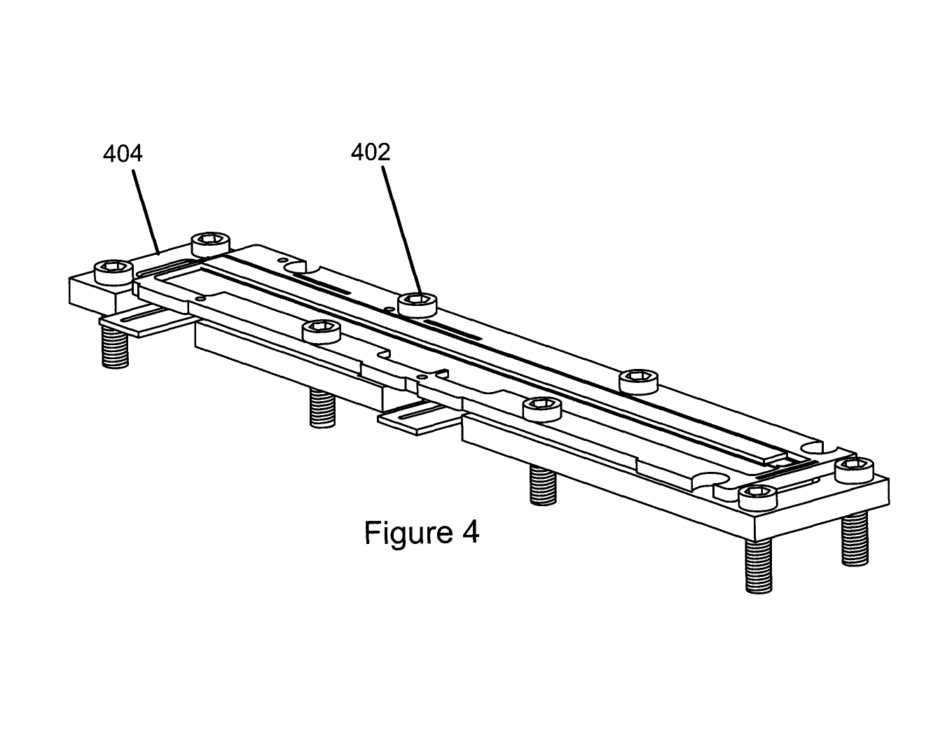

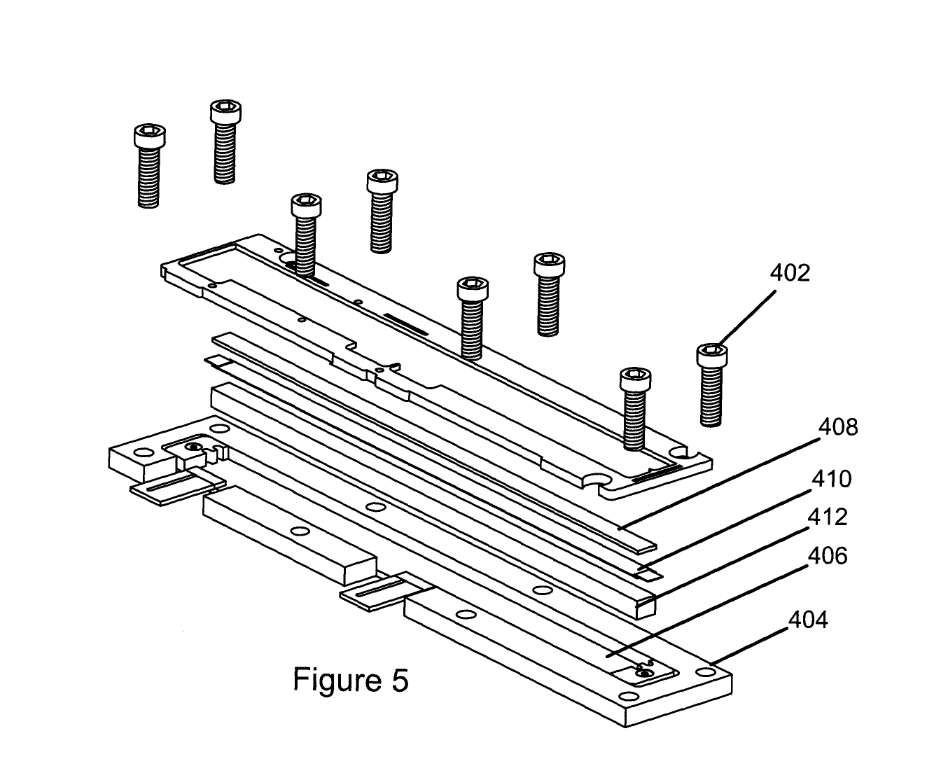

The fiber optic plate 208 is sized to cover at least the image sensor region 204. The image sensor region 204 can also be understood to be a photo diode array. Fiber optic plate 208 is secured in place by a coupling portion 210 applied to the top surface of the imaging die layer 203 and a mechanical securement apparatus such as clamp 213 is used. Further examples of the clamp 213 are shown relative to FIGS. 4 and 5. The coupling portion 210 is preferably made of organic materials such as SU-8, BCB or any other photosensitive layer which can meet the high height-to-width aspect ratio during processing. Other organic materials (e.g. such as those used for MEMS devices) can be envisaged for the coupling portion 210 as long as the refractive index remains above a predetermined threshold (e.g. at least 1.5 and preferably at least 1.60) during the photolithographic process.

In a preferred embodiment, it is envisaged to obtain an approximate uniformity of height of the resist portions 210a in the coupling portion 210 relative to each other over the full area of the imaging die layer 203 such as to aid in improving performance.

Further advantageously by forming the coupling portion 210 from organic material (e.g. the resist portions not being formed from baked resist but rather SU-8 and BCB or any other photo sensitive patternable layer with a high aspect ratio), the height of the resist portions or islands 210a can be very high (e.g. in the micron range). This height is advantageous to provide a smaller gap 222 between the individual resist portions 210a that corresponds with close spacing of the pixels.

In a preferred embodiment, the resist portions 210a provide a minimal height (e.g. above 50 micron) such as to provide a stand off and create space for wire bonds 209. In this manner, the fiber optic plate 208 provides a mechanical protection for the wire bonds 209 and the requirement for proper alignment of the fiber optic plate 208 relative to the imaging die layer 203 of the device 200 is relaxed as the wire bonds 209 will not be damaged by poor alignment. As also understood by a person skilled in the art, in some applications of the device 200 such for breast CT scans, it is important to minimize the distance between the active imaging area (e.g. imaging sensor region 204) to the chest wall. In accordance with one embodiment according to FIG. 2, the chest-wall distance can be minimized as the resist portions 210a also function as spacers and mechanical protection for the wire bonds 209 thereby allowing the pixels 205 to be placed at the edge or at a minimal spacing from the upper surface of the image sensor region 204 (and thereby of the imaging die layer 203 such as to allow the device 200 to be used as a mammographic detector with a substantially reduced chest-wall distance (e.g. distance between the pixels 205 and the chest wall) compared to a device 200 using adhesives to bond or attach the fiber optic plate to the semiconductor device or imaging die layer of the device.

That is, in existing imaging devices which use an adhesive layer (e.g. optical adhesive) between the silicon device and the fiber optic plate, the light rays would bounce between the pixels and the fiber optic plate causing cross talk and a decreased MTF. This cross talk is even higher as the adhesive layer thickness is increased through a thicker bond line as light can travel to the pixel and unintended adjacent pixels as well as potentially circular projection of rays. This cross talk is minimized through the the embodiment of FIG. 2.

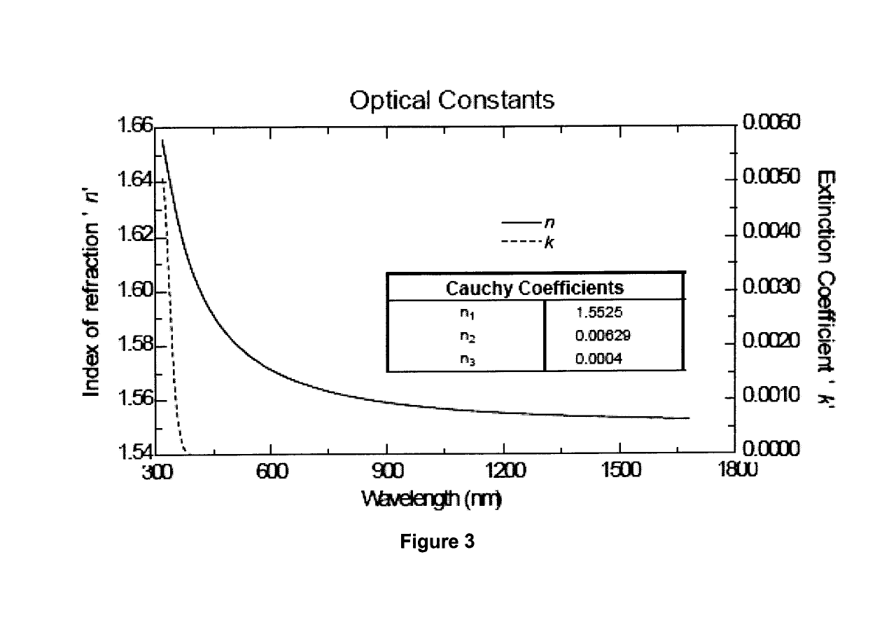

In another embodiment, the refractive index of the SU-8 photoresist forming the coupling portion 210 can range from approximately 1.6 to 1.8. A table of exemplary refractive index for SU-8-3000 is shown in FIG. 3. Specifically, a high refractive index is preferred as the higher the refractive index of the resist portions 210a, the better the performance of the light guides with respect to minimizing cross talk performance.

Referring again to FIG. 2, the coupling portion 210 can be processed or created using thin film processes to form resist portions or islands 210a having a predefined area and aspect ratio by controlling the thin film process through the sizing and shaping of the mask used as described below. In a preferred embodiment, the imaging sensor device 200 is configured for x-ray radiological or gamma ray imaging applications such that scintillator layer 211 will be exposed to incident x-rays or gamma rays, and scintillator emissions will travel though the fibers of the fiber optic plate 208 and into pixels at the imaging sensor area 204. In one example, the imaging sensor 200 can be used for x-ray mammography applications and the scintillator layer 211 is a CsI scintillator.

In reference again to FIG. 2, in another aspect, for multi-spectral imaging applications, the fiber optic plate 208 and scintillator 211 are substituted with a multi-spectral filter (not shown) which is directly placed on top of the resist portions 210a (e.g. light guides) with similar advantages discussed herein such as alignment accuracy, cross talk, etc as compared to an imaging sensor using an adhesive layer to couple the multi-spectral filter layer to the coupling portion 210 and its resist portions 210a.

The resist portions 210a can be understood to be light guides as they receive and trap the light rays within a particular resist portion 210a which is adjacent to a desired pixel in the imaging sensor region 204. The resist portions 210a can also be referred to as photoresists. That is, the high refractive index (e.g. at least 1.60) of the resist portions 210a compared to the surrounding air (e.g. refractive index of 1) causes the light rays to get trapped inside the resist portions 210a and be inhibited from leaking through the resist portions 210a to other unintended (e.g. neighbouring) pixels of the array of pixels 205.

Additionally, the resist portions 210a can provide a desired physical spacing (defined by the size and aspect ratio of the resist portions 210a during the formation process) between the fiber optic platelayer 208 and the imaging die layer 203, such as to provide desired space for wire bonds 209.

It is also preferable that the coupling portion 210 is selected from a material such that the height-to-width aspect ratio remains relatively high during the definition process of creating resist portions 210a (e.g. at least 5:1 for height/width of the resist portions 210a). High height-to-width aspect ratios allow resist portions 210a to be fabricated with near-vertical side walls to assist maintaining an air gap 222. In an exemplary embodiment, the resist portions 210a are spaced apart by at least 4 microns. In a preferred embodiment, the resist portions 210a, which can also be understood to act as individual pixel light guides, are spaced apart by at least the same spacing between corresponding pixels 205. For example, if two adjacent pixels 205 are separated by X microns, then the respective resist portions 210a corresponding to the adjacent pixels 205 are also spaced by at least X microns. Preferably, there is sufficient spacing between the individual resist portions 210a (e.g. pixel light guides) to ensure that the light rays 220 from the fiber optic plate 208 to the pixels 205 do not interfere with one another.

The resist portions 210a have a resist portion area that corresponds to the surface area of the resist portions 210a that is in contact with the corresponding pixel. The resist portion area can correspond to the entire pixel area or a portion of the pixel area. Some embodiments can have a 1:1 ratio of resist portions 210a to pixels while other embodiments can have multiple resist portions 210a per pixel. For example, the pixel can be split up into four areas and have four resist portions 210a that correspond to the pixel.

It is advantageous to have a coupling portion 210 and corresponding resist portions 210a formed from a material with a high refractive index as this allows the light rays to be primarily contained within the resist portions 210a (that is the resist portions 210a have a high refractive index relative to air gaps 222 therebetweeen) which will deter scattering of light rays to adjacent unintended pixels 205 in the image sensor region 204). That is, when one or more selected resist portions 210a have light entering from the fiber optic plate 208 thereto, then due to difference in refractive index between the selected resist portions 210a and the air gaps 222 therebetween, the light photons substantially remain within each of the one or more selected resist portions 210a and are limited from passing into the air gap 222 at the edge surfaces of the resist portions 210a (e.g. surface defined between the resist portion 210a and the air gap 222).

Further, the configuration of FIG. 2 is advantageous, as the air gaps 222 provided between the individual light guides or resist portions 210a limits trapping air in a void between the pixels 205 and the fiber optic plate 208. That is, these trenches provided as air gaps 222 ensure that air is never trapped between the pixels 205 and the fiber optic plate 208. That is, the resist portions 210a are spaced apart by a pre-defined spacing to provide air gaps 222 such as to allow the flow of air therebetween.

In one exemplary embodiment, a photolithographic process can be used for forming the resist portions 210a from the coupling portion 210 by exposing the coupling portion 210 to light such as to remove the portions between the resist portions 210a (to create the desired spacing or air gaps 222 therebetween). The amount of removal causing the spacing of the resist portions 210a (air gaps 222) is controlled by a mask preferably made of a glass plate or Quartz that acts to block the light in pre-selected portions. That is, during this process, the light penetrates into the coupling portion 210, causing a chemical reaction and similar to a photolithographic process, a developer is used for dissolving undesired areas of the coupling portion 210 to create the resist portions 210a with the desired optical air gap 222. As described earlier, the optical separation of the resist portions 210a (also referred to as optical air gap 222) is correlated to the corresponding pixel separation such that to facilitates the light rays to flow into the desired pixels and prevent scattering.

The top surfaces of resist portions 210a that make contact with the fiber optic plate can be somewhat uneven, and also resist portions 210a can have an uneven height relative to one another. In some embodiments the imaging sensor 200 can further comprises coupling oil located between the top surface of resist portions 210a and fiber optic plate 208 to limit air gaps between the resist portions 210a and the fiber optic plate 208. The coupling oil is applied in a thin layer, preferably less than one micron. The coupling oil enhances coupling of the resist portions 210a with the fiber optic plate 208 to account for the unevenness of the top surfaces of resist portions 210a and relative unevenness of the height of resist portions 210a.

In yet another embodiment, an adhesive bead (not shown) can be applied at the periphery or perimeter of the fiber optic plate 208 and/or the imaging die layer 213 to stabilize the imaging sensor 200 layers further. In this manner, the adhesive bead does not interfere with the light rays and their intended pixels.

In a further embodiment, each resist portion 210a is shaped through etching and embossing to provide a concave shape, similar to a suction cup, on a top surface of the resist portion 210a facing the fiber optic plate layer 208. Embossing can use a die that is aligned and pressed against the top surface of the resist portions 210a to create the concave shape on the top surface of resist portions 210a.

In some embodiments, the adhesive layer 202 can be used to secure the substrate plate 201 relative to the imaging die layer 203.

In some embodiments, scintillator layer 211 can be disposed on a top surface of the fiber optic plate 208. Scintillator layer 211 can be provided by deposition on the top surface of fiber optic plate 208, or alternatively as a paper strip of scintillator material. The scintillator strip may be secured onto medical imaging sensor 200 using a press-on cover (not shown). In yet other embodiments, the scintillator layer 211 and the fiber optic plate 208 can be integrated into a single integral component (referred to as SFOP). The scintillator layer 211 is a conversion layer that is excited by ionizing radiation to emit photons. In medical imaging embodiments, the scintillator layer 211 can be used to convert X-ray or gamma ray radiation into optical radiation that can be detected by the imaging die layer 203.

In this manner when the imaging sensor 200 is exposed to ionizing radiation (e.g. x-rays or gamma rays), in response, the scintillator layer 211 generates light photons. The light photons are then guided in the fibers of the fiber optic plate 208, they are then received into the resist portions 210a. The resist portions 210a serve to act as a light guide and to prevent optical cross talk such that the light is directed to a pixel that is directly adjacent to (e.g. disposed directly under or closest in distance to) the resist portion 210a and located in the imaging sensor region 204 of the imaging die layer 203.

In some embodiments, the imaging sensor 200 is held together by means of a mechanical clamp (e.g. 213, 404), or other fastening device as shown in FIGS. 2, 4 and 5 including fasteners (e.g. a plurality of screws and bolts 402 located along the edges or periphery of the clamp 404) to hold together in secure arrangement the fiber optic plate 208 (and scintillator layer 211 if present) to the imaging die layer 203 and the substrate plate 201. In FIG. 4, the CMOS imaging sensor and mechanical clamp (e.g. 402, 404) are shown in a closed position. In FIG. 5, an exploded view of the CMOS imaging sensor and the mechanical securement device (e.g. 402, 404) is shown. In FIG. 5, the mechanical securement device 404 comprises a longitudinal slot or tray 406 for receiving the imaging sensor device 412 (e.g. the imaging die layer 203 and the substrate layer 201 shown in FIG. 2). The tray 406 is further configured for receiving the fiber optic plate 416 and the foam 408. The foam 408 is compressed to create an opposing force to the compression force to assist securing the layers. The clamp 404 includes a bottom portion and a top portion for enclosing the layers as a protective box thereby securing the layers 408, 410, and 412 therein.

In other embodiments, the fastening device used to hold together the layers of the imaging sensor device 200 can be any mechanical securement device 213 which mechanically holds or secures objects tightly together to prevent movement or separation through the application of compressive force (e.g. through use of clamps and/or removably securable fasteners and screws). The compressive force can be referred to as a mechanical z-force with respect to the x-y surface of the imaging sensor 200. The mechanical securement device 213 shown in FIG. 2 or the combination of 402 and 404 is configured to allow removal of the clamp apparatus 213 (or 402 and 404) and reconfiguration where needed such as to allow replacement of the fiber optic plate 208 and/or the scintillator layer 211.

In the embodiment shown in FIG. 5, and in reference to FIG. 2, the substrate plate 201, the fiber optic plate 208 and the coupling portion 210 (e.g. 410 and 412) are secured together by mechanical force through the clamp 213 (e.g. 402, 404) and a layer of foam 408 placed on top of the fiber optic plate 208 (e.g 408 in FIG. 5) for compressing the layers.

In other embodiments, referring to FIGS. 2, 4 and 5 the imaging sensor 200 can be placed in a protective box (404 shown in FIGS. 4 and 5) surrounding the fiber optic plate 410 and the imaging device 412, the box 404 being held together relative to the layers with a plurality of fasteners (e.g. 402) for securing together the layers of the imaging sensor 412 without requiring the use of adhesive between the fiber optic plate layer 410 and the imaging die layer 203 (or semiconductor device 412).

Referring to FIGS. 2, 4 and 5, although a single removable clamp (e.g. 213) is shown, a plurality of clamps and/or fasteners can be envisaged positioned around the periphery of the outer layers of the imaging sensor device 200. In one example, the top and bottom layers of the imaging sensor device 200 can be directly contacted by one or more clamps 213 positioned around the periphery of the fiber optic plate 208 and the substrate plate 201. In another example, in the case where a scintillator layer 211 is present, then the clamp 213 would be in direct contact with the scintillator layer 211 and the substrate plate 201.

In some embodiments, a plurality of mechanical fasteners and/or clamps 213 (also shown as 402 and 404) can be used to mechanically hold together the layers of the imaging sensor device 200. In one embodiment, the mechanical fasteners 213 (e.g. 402) may comprise a continuous application of fasteners (e.g. 402) around the perimeter of fiber optic plate 208, or a discontinuous application at discrete locations around the perimeter of fiber optic plate 208, or any combination thereof.

Although preferred embodiments of the invention have been described herein with regard to x-ray imaging sensors, it is contemplated, and indeed it will be understood by those skilled in the art, that the solutions presented herein may be applied to other types of imaging sensors for the detection of X-ray or gamma radiation, such as but not limited to, non-destructive testing and crystallography. Accordingly, a person of ordinary skill in the art will understand that the specific embodiments described herein, while illustrative may not necessarily be comprehensive, and various modifications may be made without departing from the scope of the invention as defined by the claims.

What is claimed is:

1. An imaging sensor, the sensor comprising:
a substrate plate having an upper surface;
an imaging die layer on the upper surface of the substrate plate, the imaging die layer having an active image sensor region, the active image sensor region comprising a plurality of pixels, the pixels adapted for receiving light photons, each said pixel having a pixel area for receiving light photons;
a fiber optic plate provided above the imaging die layer having a plurality of parallel wave guides and at least one of the pixels corresponding to at least two wave guides; and
a coupling portion comprising a plurality of resist portions, each of the resist portions being located adjacent to a corresponding one of the pixels and having a resist portion area corresponding to at least a portion of the pixel area of the corresponding one of the pixels, each resist portion configured to act as a light guide such as to receive and direct the light photons from the fiber optic plate to the corresponding one of the pixels directly adjacent thereto, the coupling portion located between the imaging die layer and the fiber optic plate, adjacent resist portions defining an air gap.

2. The sensor of claim 1, wherein the imaging sensor is adapted for exposure to ionizing radiation, the image sensor further comprising a scintillator layer deposited above a top surface of the fiber optic plate, the scintillator layer configured for converting the ionizing radiation to light photons.

3. The sensor of claim 2, wherein the ionizing radiation is any one of X-rays and gamma rays.

4. The sensor of claim 1, wherein each resist portion directs the light photons from the fiber optic plate only to the corresponding one of the pixels directly adjacent to the resist portion such as to minimize optical cross-talk.

5. The sensor of claim 1 wherein the resist portions are spaced apart by at least a pre-defined optical gap.

6. The sensor of claim 1, further comprising a securement apparatus having a removable mechanical clamp applied around a perimeter of the fiber optic plate and the substrate plate and directly in contact therewith.

7. The sensor of claim 1 wherein the scintillator layer and the fiber optic plate are a single integral scintillator fiber optic plate layer.

8. The sensor of claim 1 wherein the substrate plate layer, the fiber optic plate layer and the coupling portion are secured together by mechanical force and a layer of foam placed either on top of or below the fiber optic plate is configured for compressing the fiber optic plate to the coupling portion.

9. The sensor of claim 1 wherein the resist portions are formed from an optical transparent photosensitive layer that is exposed to light during a photo-lithographical process for forming each of the resist portion areas and providing at least a predefined height-to-width aspect ratio.

10. The sensor of claim 9, wherein the resist portions are provided with a height to provide for a wire bond between the imaging die layer and the fiber optic plate.

11. The sensor of claim 8 wherein the resist portions are made of an organic material for providing a photosensitive patternable layer.

12. The sensor of claim 11 wherein the resist portions are formed from the group consisting of SU-8 and BCB.

13. The sensor of claim 9, wherein the predefined aspect ratio for each resist portion is at least 5:1 for height/width.

14. The sensor of claim 1, wherein a top surface of at least one resist portion is concave.

15. The sensor of claim 1, wherein the imaging sensor is an optical sensor selected from the group consisting of: a CMOS, SPAD, a CCD sensor, amorphous silicon detector, and organic material-based light sensor.

16. The sensor of claim 1 wherein the imaging sensor further comprises coupling oil located between the a top surface of the resist portions to minimize air gaps between the resist portions and the fiber optic plate.

17. The sensor of claim 1, further comprising a mechanical securement apparatus configured for removal such as to allow replacement of at least one of the fiber optic plate and the scintillator.

18. The sensor of claim 1, further comprising a mechanical securement apparatus configured for removal and reattachment such as to allow optical realignment of the imaging die layer, the fiber optic plate and the coupling portion relative to one another.

19. The sensor of claim 1 wherein the resist portions are formed into their corresponding resist portion areas by a process selected from one of etching process and lithography.

20. The sensor of claim 11 wherein the resist portions are shaped by any one of applying thermal curing process and embossing to provide the resist portion area.

21. The sensor of claim 11 wherein the resist portion areas have a refractive index of at least 1.60.

22. The sensor of claim 1 wherein the substrate plate is selected from the group consisting of: glass, CE-7 and metal plate.

23. The sensor of claim 1 wherein each set of two resist portions being spaced apart by a pre-defined distance such as to create an air gap therebetween, the air gap for facilitating the flow of air between the fiber optic plate and the imaging die layer.
